(19) United States
(12) Patent Application Publication
(10) Pub. No.: US 2023/0411263 A1
(43) Pub. Date: Dec. 21, 2023

(54) MODULAR SEMICONDUCTOR DEVICES AND ELECTRONIC DEVICES INCORPORATING THE SAME

(71) Applicant: STATS ChipPAC Pte. Ltd., Singapore (SG)

(72) Inventors: SooHan PARK, Incheon (KR); KyungEun KIM, Incheon (KR); YouJin SHIN, Incheon (KR); HyeSun KIM, Incheon (KR)

(21) Appl. No.: 18/332,777

(22) Filed: Jun. 12, 2023

(30) Foreign Application Priority Data
Jun. 15, 2022 (CN) 202210678569.8

(51) Int. Cl. H01L 23/498; H01L 25/16; H01L 25/03; H01L 21/56; H01L 23/00; H01L 25/00; H01L 23/31; H01L 23/538

(52) U.S. Cl. CPC H01L 23/49827; H01L 25/16; H01L 25/03; H01L 21/568; H01L 21/561; H01L 24/24; H01L 24/96; H01L 24/82; H01L 25/50; H01L 23/3185; H01L 23/49816; H01L 23/5389; H01L 23/5385; H01L 2224/96; H01L 2224/24155; H01L 2224/24101; H01L 2224/82105; H01L 2224/2402; H01L 2224/82005

(57) ABSTRACT

A modular semiconductor device comprises: an encapsulant layer with an encapsulant bottom surface and an encapsulant top surface, wherein the encapsulant layer comprises a component region and an interlayer connection region; wherein the semiconductor component comprises a component conductive pattern exposed from the encapsulant bottom surface; an interlayer connection array disposed within the interlayer connection region, wherein the interlayer connection array comprises one or more conductive vias each extending between the encapsulant bottom surface and the encapsulant top surface; and an interposer layer laminated on the encapsulant layer and having an interposer bottom surface and an interposer top surface, wherein the interposer top surface is in contact with the encapsulant bottom surface; wherein the interposer layer comprises an interposer conductive pattern on the interposer bottom surface, and an interposer interconnection structure electrically coupled to the component conductive pattern, the interposer conductive pattern and the one or more conductive vias.

### TECHNICAL FIELD

The present application generally relates to semiconductor technology, and more particularly, to modular semiconductor devices and electronic devices incorporating such modular semiconductor devices.

### BACKGROUND OF THE INVENTION

Semiconductor devices are commonly found in modern electronic products, which perform a wide range of functions, such as signal processing, high-speed calculations, transmitting and receiving electromagnetic signals, controlling electronic devices, and creating visual images for television displays. An integrated circuit can be fabricated within a semiconductor die. The semiconductor die can also be referred to as a chip, which has a surface that includes conductive patterns for connecting the chip with external devices.

With the continued improvement in electronic products, it is desired to integrate more and more semiconductor dice in a single package. However, due to the limited budget in the layout of a substrate for mounting semiconductor dice, there is a need for an improved packaging technology for semiconductor devices.

### SUMMARY OF THE INVENTION

An objective of the present application is to provide a semiconductor device with reduced occupation of the layout of a substrate for the semiconductor device.

According to an aspect of the present application, a modular semiconductor device is provided. The modular semiconductor device comprises: an encapsulant layer with an encapsulant bottom surface and an encapsulant top surface, wherein the encapsulant layer comprises a component region and an interlayer connection region; a semiconductor component disposed within the component region, wherein the semiconductor component comprises a component conductive pattern exposed from the encapsulant bottom surface; an interlayer connection array disposed within the interlayer connection region, wherein the interlayer connection array comprises one or more conductive vias each extending between the encapsulant bottom surface and the encapsulant top surface; and an interposer layer laminated on the encapsulant layer and having an interposer bottom surface and an interposer top surface, wherein the interposer top surface is in contact with the encapsulant bottom surface; and wherein the interposer layer comprises an interposer conductive pattern on the interposer bottom surface, and an interposer interconnection structure which is electrically coupled to the component conductive pattern, the interposer conductive pattern and the one or more conductive vias.

According to another aspect of the present application, an electronic device is provided. The electronic device comprises: a substrate comprising a substrate interconnection structure; a base semiconductor component mounted on the substrate and electrically coupled to the substrate interconnection structure; one or more base vias mounted on the substrate and electrically coupled to the substrate interconnection structure; a first modular semiconductor device stacked over the base semiconductor component and the one or more base vias, wherein the first modular semiconductor device comprises: an encapsulant layer with an encapsulant bottom surface and an encapsulant top surface, wherein the encapsulant layer comprises a component region and an interlayer connection region; a semiconductor component disposed within the component region, wherein the semiconductor component comprises a component conductive pattern exposed from the encapsulant bottom surface; an interlayer connection array disposed within the interlayer connection region, wherein the interlayer connection array comprises one or more conductive vias each extending between the encapsulant bottom surface and the encapsulant top surface; and an interposer layer laminated on the encapsulant layer and having an interposer bottom surface and an interposer top surface, wherein the interposer top surface is in contact with the encapsulant bottom surface; and wherein the interposer layer comprises an interposer conductive pattern on the interposer bottom surface, and an interposer interconnection structure which is electrically coupled to the component conductive pattern, the interposer conductive pattern and the one or more conductive vias; and wherein the interposer conductive pattern is electrically coupled to the one or more base vias.

According to a further aspect of the present application, methods for making the modular semiconductor devices and electronic devices in the aforementioned aspects are provided.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate an electronic device with a modular semiconductor device according to an embodiment of the present application.

FIGS. 2 and 3 illustrate electronic devices with several modular semiconductor devices according to some embodiments of the present application.

FIG. 4 illustrates an electronic device with a modular semiconductor device according to another embodiment of the present application.

FIG. 5 illustrates an electronic device with a modular semiconductor device according to another embodiment of the present application.

FIGS. 6A to 6I illustrate a method for making an electronic device with a modular semiconductor device according to an embodiment of the present application.

FIGS. 7A to 7F illustrate a method for making a modular semiconductor device according to an embodiment of the present application.

FIGS. 8A to 8G illustrate a method for making a modular semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

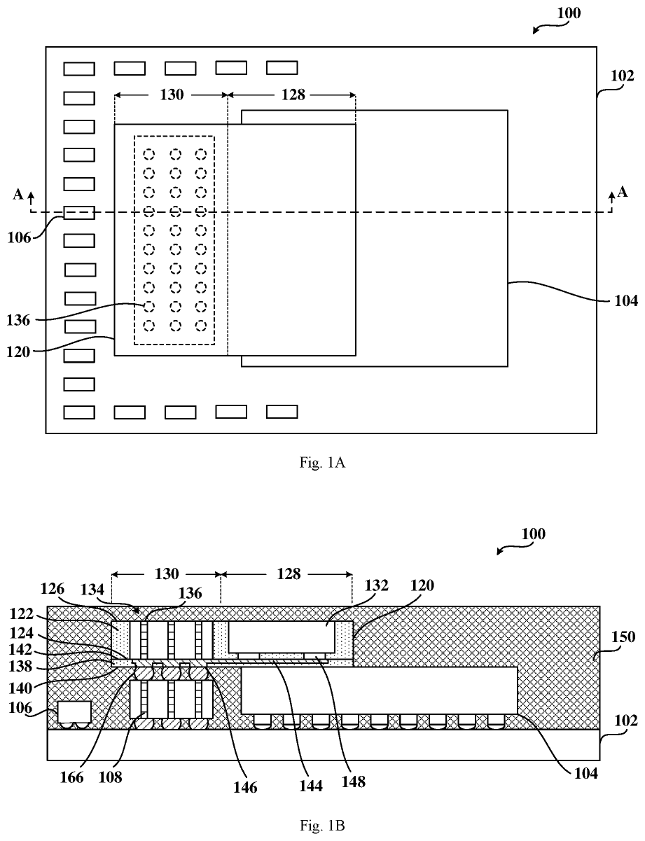

FIGS. 1A and 1B illustrate an electronic device 100 with a modular semiconductor device 120 according to an embodiment of the present application. FIG. 1A shows a top view of the electronic device 100, while FIG. 1B shows a cross sectional view of the electronic device 100 along a section line AA in FIG. 1A.

As shown in FIGS. 1A and 1B, the electronic device 100 includes a substrate 102 on which one or more components are mounted. The substrate 102 may include one or more insulating or passivation layers and one or more substrate interconnection structures (not shown) formed in the insulating or passivation layers. Each substrate interconnection structure may include one or more conductive vias formed through the insulating or passivation layers, and one or more conductive layers formed on a top surface and/or a bottom surface of the substrate 102. The substrate 102 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate 102 can also be a multi-layer flexible laminate, ceramic, copper clad laminate, or glass. In some embodiments, the substrate interconnection structures or redistribution layers (RDL) inside the substrate 102 can be formed using sputtering, electrolytic plating, electroless plating, or other suitable deposition process. The conductive vias and layers may be one or more layers of Al, Cu, Sn, Ni, Au, Ag, titanium (Ti), tungsten (W), or other suitable electrically conductive material.

A base semiconductor component 104 is mounted on the substrate 102, along with various other discrete components 106 such as capacitors, resistors or similar electronic components, or board-to-board connectors. In some embodiments, the base semiconductor component 104 may include a semiconductor die or a semiconductor package to implement analog or digital circuits. For example, a semiconductor die can be formed in a flip chip manner and may be mounted onto the top surface of the substrate 102 such that conductive patterns of the semiconductor die can be welded to the substrate interconnection structures in the substrate 102. In some other embodiments, a semiconductor die may include bond pads that may be connected to the substrate interconnection structures by wire bonding. Through the substrate interconnection structures, the base semiconductor component 104 can be electrically coupled to an external electronic device or the discrete components 106 of the electronic device 100, as elaborated below.

Although not shown in FIG. 1B, a portion of the substrate interconnection structures may be embedded within the substrate 102 and under the base semiconductor component 104. Furthermore, another portion of the substrate interconnection structure may extend laterally along the substrate 102 and may be under some other components 106 or structures of the electronic device 100. As shown in FIG. 1B, one or more base vias 108 are mounted on the substrate 102 and electrically coupled to the substrate interconnection structures. In some embodiments, the base vias 108 can be bonded to or welded to the substrate interconnection structures to ensure electrical connection therebetween. In the embodiment shown in FIG. 1B, the base vias 108 are formed as a protrusion e-bar structure which is a block or panel with multi-layered conductive posts. The block or panel of the protrusion e-bar structure can be made of one or more layers of silicon dioxide (SiO₂), silicon nitride (Si₃N₄), silicon oxynitride (SiON), tantalum pentoxide (Ta₂O₅), aluminum oxide (Al₂O₃), solder resist, polyimide, benzocyclobutene (BCB), polybenzoxazoles (PBO), and other material having similar insulating and structural properties. The block or panel of the protrusion e-bar structure can also be a multi-layer flexible laminate, ceramic, copper clad laminate, glass, epoxy molding compound, or semiconductor wafer. In another embodiment, the block or panel of the protrusion e-bar structure can also be any suitable laminate interposer, PCB, wafer-form, strip interposer, leadframe, or other type of substrate. The block or panel may include one or more laminated layers of polytetrafluoroethylene (PTFE) pre-impregnated (prepreg), FR-4, FR-1, CEM-1, or CEM-3 with a combination of phenolic cotton paper, epoxy, resin, woven glass, matte glass, polyester, and other reinforcement fibers or fabrics. The base vias 108 or particularly the conductive posts can be one or more layers of Al, Cu, Sn, Ni, Au, Ag, or other suitable electrically conductive material, and can be formed using PVD, CVD, electrolytic plating, electroless plating process, or other suitable metal deposition process. In some embodiments, the protrusion e-bar structure can be preformed as a single piece so that it can be easily mounted onto the substrate 102.

As shown in FIG. 1B, the base vias 108 have a thickness substantially equal to that of the base semiconductor component 104 (including its bond pads or conductive bumps 166). In this way, additional semiconductor components or devices, which is the modular semiconductor device 120 in the embodiment, can be stacked over the base semiconductor component 104 and the base vias 108. The modular semiconductor device 120 is preformed as a single piece, and thus it is easy to place it above the base semiconductor component 104, without complicated processes such as interconnection deposition. Furthermore, a global encapsulant layer 150 can be formed to cover the various components and devices on the substrate 102 for protection purpose. For example, the encapsulant layer 150 can be formed by depositing an encapsulant material after the placement of the modular semiconductor device 120 over the base semiconductor component 104.

In particular, the modular semiconductor device 120 includes an encapsulant layer 122, which encapsulates the other subcomponents and protects them from exterior damages. Also, the encapsulant layer 122 can assemble the subcomponents of the modular semiconductor device 120 together, so that they can be moved and processed together during a later operation. As shown in FIG. 1B, the encapsulant layer 122 has an encapsulant bottom surface 124 and an encapsulant top surface 126 opposite to the encapsulant bottom surface 124. Furthermore, the encapsulant layer 122 can include a component region 128 and an interlayer connection region 130 adjacent to the component region 128. When attached with the base semiconductor component 104 and the base vias 108, the component region 128 is substantially aligned with the base semiconductor component 104, and the interlayer connection region 130 is substantially aligned with the base vias 108.

A semiconductor component 132 is disposed within the component region 128, which is used to implement digital or analog circuits. In some embodiments, the semiconductor component 132 can be a semiconductor die or a semiconductor package. It is desired to electrically couple the semiconductor component 132 with the base semiconductor component 104 thereunder, so as to achieve a compact structure of the electronic device 100 and reduced the occupation of too much layout of the substrate 102. In order to connect the two, the semiconductor component 132 includes a component conductive pattern 148 exposed from the encapsulant bottom surface 124, which functions as an interface between the semiconductor component 132 with other exterior components or devices.

The modular semiconductor device 120 further includes an interlayer connection array 134 disposed within the interlayer connection region 130. The interlayer connection array 134 includes one or more conductive vias 136 each extending between the encapsulant bottom surface 124 and the encapsulant top surface 126. That is, the conductive vias 136 are exposed from both of the encapsulant bottom surface 124 and the encapsulant top surface 126, and achieve a vertical signal path that passes through the interlayer connection region 130. In the embodiment shown in FIG. 1B, the interlayer connection array 134 is formed as a protrusion e-bar structure with conductive vias made of one or more layers of Al, Cu, Sn, Ni, Au, Ag, or other suitable electrically conductive material, which may be similar to the base vias 108 and thus is not elaborated herein. Similarly, the interlayer connection array 134 formed as the protrusion e-bar structure can be preformed as a single piece so that it can be easily mounted with other components or structures.

In some embodiments, the encapsulant layer 122 may have a thickness equal to that of the semiconductor component 132 to reduce the overall thickness of the modular semiconductor device 120. However, in some other embodiments, the encapsulant layer 122 may have a thickness greater than that of the semiconductor component 132, to protect the top surface of the semiconductor component 132.

An interposer layer 138 is laminated on the encapsulant layer 122. The interposer layer 138 has an interposer bottom surface 140 and an interposer top surface 142 opposite to the interposer bottom surface 140. The interposer top surface 142 is in contact with the encapsulant bottom surface 124. When the modular semiconductor device 120 is attached with the base semiconductor component 104 and the base vias 108, the interposer top surface 140 is in contact with their respective top surfaces directly or through interconnect solder balls (e.g., the solder balls 166). In particular, the interposer layer 138 includes an interposer interconnection structure 144 which is electrically coupled to the component conductive pattern 148 and the one or more conductive vias 136. In this way, the semiconductor component 132 can be electrically connected to the conductive vias 136. Furthermore, the interposer layer 138 also includes an interposer conductive pattern 146 on the interposer bottom surface 140, which is electrically coupled to the interposer interconnection structure 144 as well. As such, the interposer conductive pattern 146 serves as an interface of the modular semiconductor device 120 on its bottom side, to achieve signal exchange with the base semiconductor component 104 under it. On the other side of the modular semiconductor device 120, i.e., the top surface of the encapsulant layer 122, the exposed top surface of the conductive vias 136 serves as another interface of the modular semiconductor device 120 to achieve signal exchange with other semiconductor components (not shown) mounted above the modular semiconductor device 120.

In the embodiment shown in FIGS. 1A and 1B, the stack of semiconductor component/devices are arranged in an asymmetric layout. That is, the modular semiconductor device 120 is arranged at one side of the overall electronic device 100, rather than occupying the entire layout of the electronic device 100. Since the modular semiconductor device 120 does not overlap an entire top surface of the base semiconductor component 104, heat dissipated from the base semiconductor component 104 does not directly affect an entirety of the modular semiconductor device 120 and vice versa. This asymmetric layout can help to improve the warpage control of the overall device. Also, the base semiconductor component 104 may not fully overlap with the semiconductor component 132 of the modular semiconductor device 120. For example, the semiconductor component 132 may have a size smaller than the base semiconductor component 104.

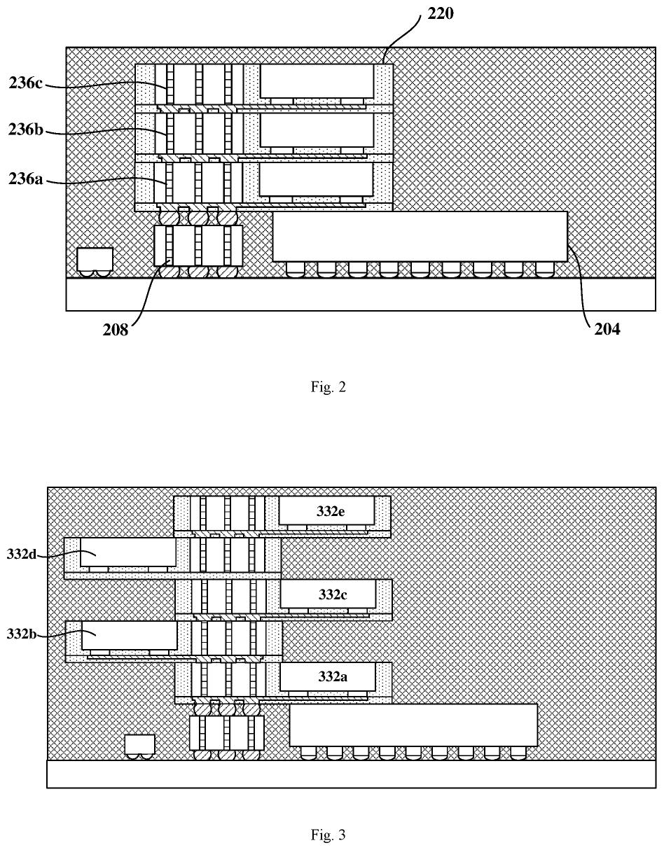

Although it is shown in FIG. 1B that only one modular semiconductor device 120 is stacked over the base semiconductor component 104 and electrically coupled to the base semiconductor component 104 through the interconnected base vias 108 and interconnect solder balls (e.g., the solder balls 166), in some other embodiments, one or more additional modular semiconductor devices can be further stacked over the modular semiconductor device 120 similarly, as illustrated in FIGS. 2 and 3.

In the embodiment shown in FIG. 2, three modular semiconductor devices 220 are stacked over a base semiconductor component 204, and all of the semiconductor components contained in the electronic device can be electrically coupled together through a “hub” of conductive vias including base vias 208, and a first set of conductive vias 236a, a second set of conductive vias 236b and a third set of conductive vias 236c of the modular semiconductor devices 220. All the modular semiconductor devices 220 have conductive structures exposed from its top surface and bottom surface, therefore they can be electrically coupled to the respective devices above and/or below them. Furthermore, in the embodiment shown in FIG. 3, five modular semiconductor devices are stacked over the base semiconductor component in an alternate arrangement with respect to a vertical “hub” of conductive vias. Since the active semiconductor components 332a to 332e of the modular semiconductor devices are not very close to each other, heat management of such arrangement can be improved. It can be appreciated that the exposed conductive structures of adjacent modular semiconductor devices can be bonded together via solder materials to achieve electrical connection.

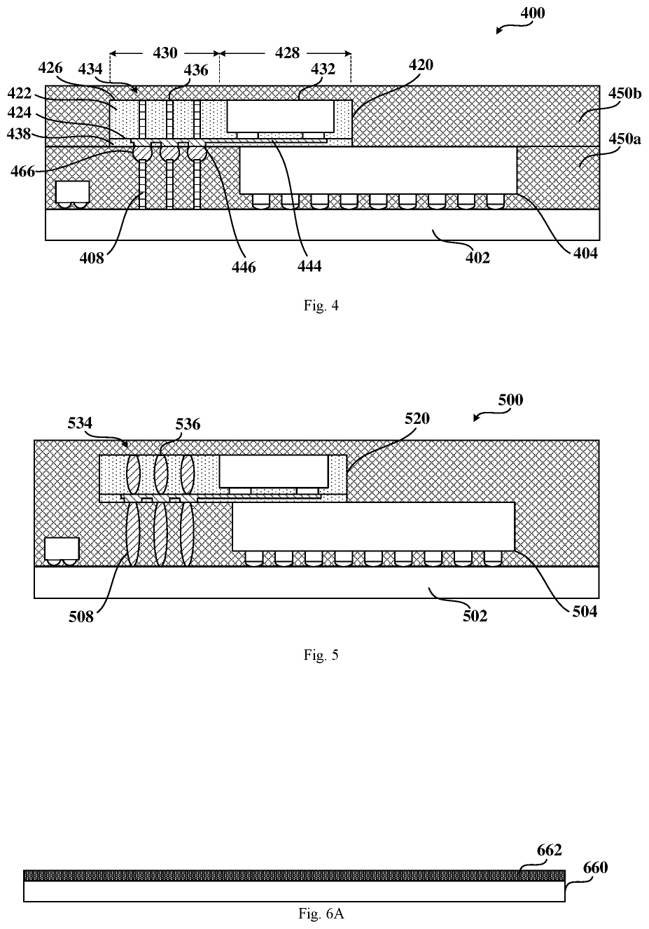

Although the base vias 108 and the interlayer connection array 134 shown in FIGS. 1A and 1B are formed as protrusion e-bar structures, they can be formed as any other suitable interconnection structures. FIGS. 4 and 5 show two modular semiconductor devices with different interconnection structures according to some embodiments of the present application.

As shown in FIG. 4, an electronic device 400 includes a substrate 402. A base semiconductor component 404 is mounted onto the substrate 402 and electrically coupled to substrate interconnection structures (not shown) formed inside the substrate 402. One and more base vias 408 are also formed on the substrate 402 to connect the substrate interconnection structures to an upper modular semiconductor device 420. The base vias 408 are made of conductive pillars which are separated from each other by an encapsulant layer 450a. The conductive pillars of the base vias 408 can be one or more layers of Al, Cu, Sn, Ni, Au, Ag, or other suitable electrically conductive material, and can be formed using PVD, CVD, electrolytic plating, electroless plating process, or other suitable metal deposition process. In some embodiments, the conductive pillars 408 can be formed after the base semiconductor component 404 is mounted on the substrate 402. Then, an encapsulant material can be deposited on the conductive pillars 408 and the base semiconductor component 404 to form the encapsulant layer 450a. Before the modular semiconductor device 420 is mounted on the encapsulant layer 450a, the encapsulant layer 450a can be planarized, and etched (e.g., by a laser beam) to expose top surfaces of the conductive pillars 408. Solder balls 466 may be placed on the top surfaces of the conductive pillars 408. In this way, the modular semiconductor device 420 can be placed above the conductive pillars 408 and be electrically coupled to the conductive pillars 408 and thus the base semiconductor component 402.

Still referring to FIG. 4, the modular semiconductor device 420 has a similar structure as the modular semiconductor device 120 shown in FIGS. 1A and 1B, expect for an interlayer connection array 434 formed as a set of conductive pillars 436. The conductive pillars of the interlayer connection array 434 are separated from each other by an encapsulant layer 422. In particular, the conductive pillars 436 are formed in an interlayer connection region 430 of the encapsulant layer 422 and besides a semiconductor component 432 in a component region 428 of the encapsulant layer 422. The conductive pillars 436 extend between an encapsulant top surface 426 and an encapsulant bottom surface 424. At the encapsulant bottom surface 424, the conductive pillars 436 are electrically coupled to an interposer interconnection structure 444 within an interposer layer 438 which is laminated under the encapsulant layer 422. Furthermore, the interposer layer 438 also includes an interposer conductive pattern 446, which is electrically coupled to the interposer interconnection structure 444. As such, the interposer conductive pattern 446 serves as an interface of the modular semiconductor device 420 on its bottom side, to achieve signal exchange with the base semiconductor component 404 under it. The modular semiconductor device 420 can be encapsulated by another encapsulant layer 450b. In some embodiments, the encapsulant layer 450b and the encapsulant layer 450a can be formed in a single process rather than formed separately in two processes, for example, after the modular semiconductor device 420 is placed over the base semiconductor component 404.

As shown in FIG. 5, another modular semiconductor device 500 includes a base semiconductor component 504 mounted on a substrate 502 and a modular semiconductor device 520 mounted above the base semiconductor component 504. Different from the embodiment shown in FIG. 4, base vias 508 and conductive vias 536 of an interlayer connection array 534 are formed as solder balls. The solder balls can have different sizes or thicknesses, depending on the respective semiconductor components disposed in the same layers as them.

As aforementioned, each of the modular semiconductor devices shown in FIGS. 1A to 1B and FIGS. 2 to 5 can be preformed as a single piece. In this way, it is easier to stack such modular semiconductor devices onto a substrate where one or more base semiconductor components are mounted. In some embodiments, a plurality of semiconductor components can be placed on a carrier and then they can be packaged with a plurality of conductive vias, which are subsequently singulated into separated modular semiconductor devices in the same batch. Such “panel-level” packaging process can significantly increase the productivity of the modular semiconductor devices. Moreover, the semiconductor components can be pretested before the packaging process, which also improve yield of the resulting modular semiconductor devices by discarding unqualified semiconductor components before the packaging process.

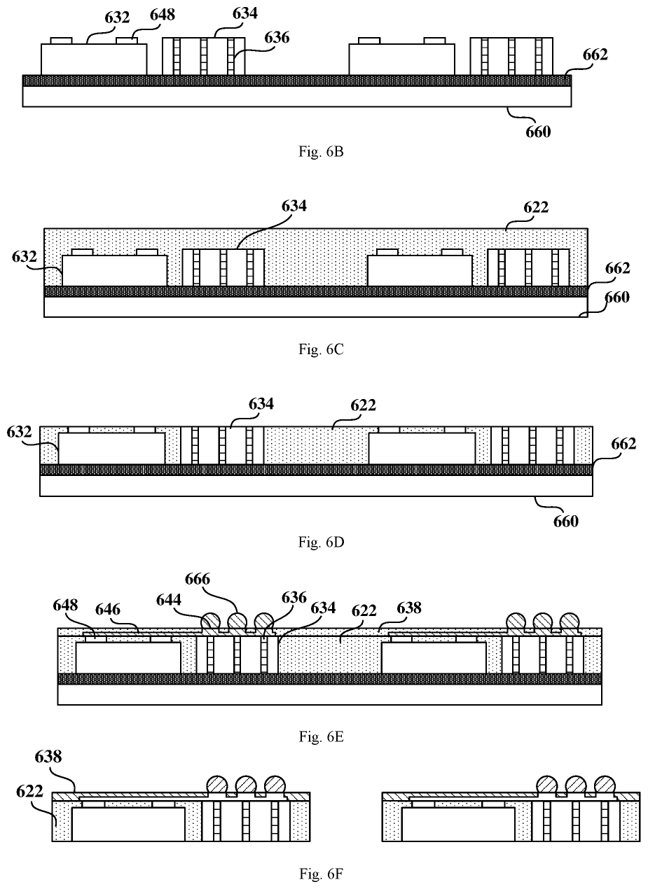

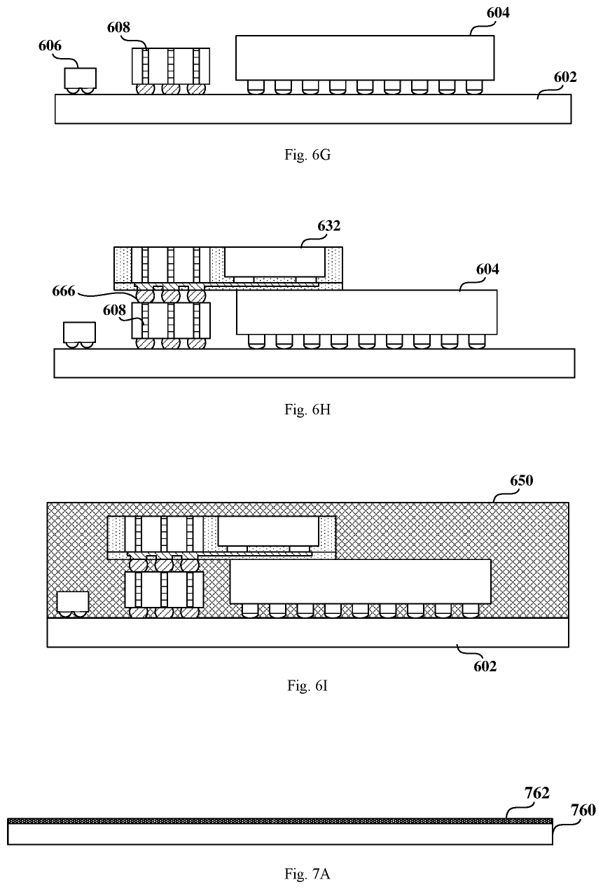

FIGS. 6A to 61 illustrate a method for making an electronic device shown in FIGS. 1A to 1B, according to an embodiment of the present application.

As shown in FIG. 6A, a carrier 660 such as a glass carrier or a metal carrier can be provided, with its top surface covered by a temporary bond layer 662 such as an adhesive tape. The adhesive tape can be a polyimide film, for example. The temporary bond layer 662 can protect the carrier 660 in the manufacturing process and temporarily attach the other layers and components with the carrier 660.

As shown in FIG. 6B, one or more semiconductor component 632 and one or more interlayer connection array 634 can be placed on the temporary bond layer 662. The interlayer connection array 634 can be placed besides the semiconductor component 632. In particular, the semiconductor component 632 includes a component conductive pattern 648 which is oriented upward away from the carrier 660. The interlayer connection array 634 has one or more conductive vias 636. The interlayer connection array 634 has a height equal to that of the semiconductor component 632, such that top surfaces of the conductive vias 636 and the component conductive pattern 648 are generally at the same level. In the embodiment, the interlayer connection array 634 is formed as a protrusion e-bar structure, which can be pre-formed.

Next, as shown in FIG. 6C, an encapsulant material can be deposited on the carrier 660, or particularly on the temporary bond layer 662, to form an encapsulant layer 622. The encapsulant layer 622 can encapsulate the semiconductor component 632 and the interlayer connection array 634. In some embodiments, the encapsulant layer 622 can be deposited using a molding process.

Afterwards, as shown in FIG. 6D, the encapsulant layer 622 may be thinned, e.g., using a back-grinding process, to remove the excess encapsulant material above the semiconductor component 632 and the interlayer connection array 634. In this way, the semiconductor component 632 and the interlayer connection array 634 and respective conductive structures on their respective top surfaces can be exposed for further processing.

As shown in FIG. 6E, an interposer layer 638 can be laminated on the encapsulant layer 622. The interposer layer 638 includes at least one an interposer conductive pattern 646 on an exposed surface of the interposer layer 638, and at least one interposer interconnection structure 644. The at least one interposer interconnection structure 644 is electrically coupled to the interposer conductive pattern 646, the component conductive pattern 648 and the one or more conductive vias 636 of the interlayer connection array 634. In some embodiments, the interposer interconnection structure 644 can include electrically conductive layers or redistribution layers (RDL) inside an interposer substrate, and can be formed using sputtering, electrolytic plating, electroless plating, or other suitable deposition process. The conductive layers may be one or more layers of Al, Cu, Sn, Ni, Au, Ag, titanium (Ti), tungsten (W), or other suitable electrically conductive material. In the embodiment shown in FIG. 6E, solder balls 666 are bonded to the respective interposer conductive patterns 646, to facilitate the subsequent attachment process.

As shown in FIG. 6F, the encapsulant layer 622 and the interposer layer 638 which are laminated together can be singulated into individual modular semiconductor devices. Each of the modular semiconductor devices may include a semiconductor component and an interlayer connection array. Afterwards, the individual modular semiconductor devices can be removed from the carrier.

A modular semiconductor device can be packaged with other semiconductor components to form a stacked structure. As shown in FIG. 6G, a substrate 602 with a base semiconductor component 604 and various other discrete components 606 is provided. The substrate 602 also has one or more base vias 608 formed thereon. In the embodiment, the base vias 608 are formed as a protrusion e-bar structure, similar as the interlayer connection array of the modular semiconductor device. Next, as shown in FIG. 6H, the modular semiconductor device can be stacked over the base semiconductor component 604 and the base vias 608, and the semiconductor component 632 of the modular semiconductor device can be electrically coupled to the base semiconductor component 604 through the base vias 608 and the solder balls 666.

Afterwards, as shown in FIG. 6I, another encapsulant material can be deposited on the substrate 602 to form an encapsulant layer 650 which protects all the components from exterior environment. It can be appreciated that more modular semiconductor devices can be stacked on the substrate 602, which can all be encapsulated by the encapsulant material.

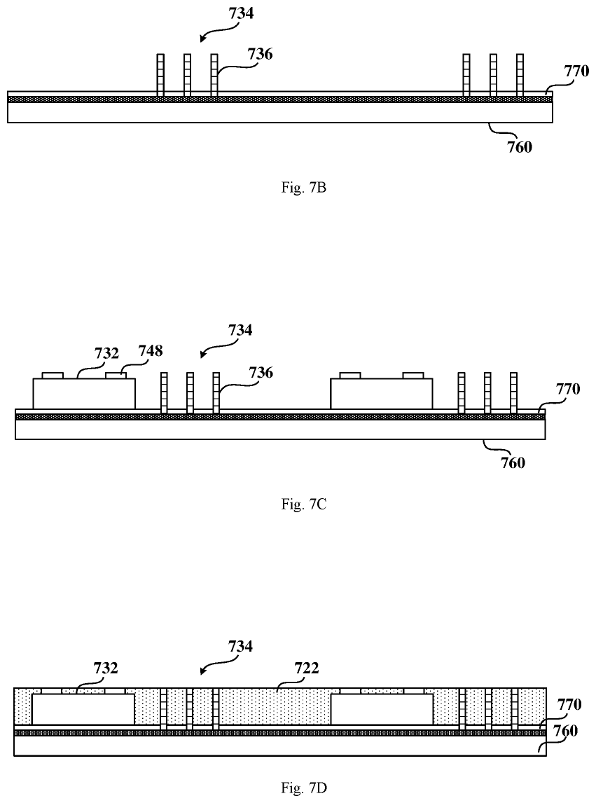

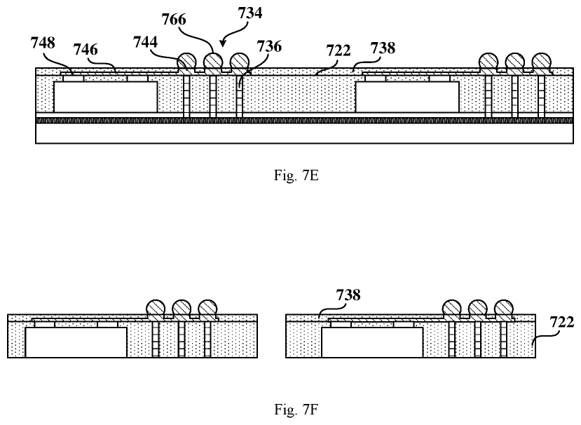

FIGS. 7A to 7F illustrate a method for making a modular semiconductor device shown in FIG. 4, according to an embodiment of the present application.

As shown in FIG. 7A, a carrier 760 such as a glass carrier or a metal carrier can be provided, with its top surface covered by a temporary bond layer 762 such as an adhesive tape. The adhesive tape can be a polyimide film, for example. The temporary bond layer 762 can protect the carrier 760 in the manufacturing process and temporarily attach the other layers and components with the carrier 760. In some embodiments, the temporary bond layer 762 can be omitted.

As shown in FIG. 7B, a temporary substrate layer 770 can be formed on the substrate 760. One or more conductive layers (not shown) can be formed within the temporary substrate layer 770, which function as anchors for one or more interlayer connection arrays 734. In the embodiment, each interlayer connection array 734 can include one or more conductive pillars 736 which extend upward from the temporary substrate layer 770.

As shown in FIG. 7C, one or more semiconductor components 732 can be placed on the temporary substrate layer 770. The semiconductor components 732 can be placed besides interlayer connection arrays 734, respectively. In particular, the semiconductor component 732 includes a component conductive pattern 748 which is oriented upward away from the carrier 760. The interlayer connection array 734 has a height equal to that of the semiconductor component 732, such that top surfaces of the conductive pillars 736 and the component conductive pattern 748 are generally at the same level.

Next, as shown in FIG. 7D, an encapsulant material can be deposited on the carrier 760, or particularly on the temporary substrate layer 770, to form an encapsulant layer 722. The encapsulant layer 722 can encapsulate the semiconductor component 732 and the interlayer connection array 734. The encapsulant layer 722 may be thinned, e.g., using a back-grinding process, to remove the excess encapsulant material above the semiconductor component 732 and the interlayer connection array 734.

As shown in FIG. 7E, an interposer layer 738 can be laminated on the encapsulant layer 722. The interposer layer 738 includes at least one an interposer conductive pattern 746 on an exposed surface of the interposer layer 722, and at least one interposer interconnection structure 744. The at least one interposer interconnection structure 744 is electrically coupled to the interposer conductive pattern 746, the component conductive pattern 748 and the one or more conductive pillars 736 of the interlayer connection array 734. Furthermore, solder balls 766 are bonded to the respective interposer conductive pattern 746, to facilitate the subsequent attachment process.

As shown in FIG. 7F, the encapsulant layer 722 and the interposer layer 738 which are laminated together can be singulated into individual modular semiconductor devices. Each of the modular semiconductor devices may include a semiconductor component and an interlayer connection array. Afterwards, the individual modular semiconductor devices can be removed from the carrier, and the temporary substrate layer can be removed from the singulated modular semiconductor devices as well.

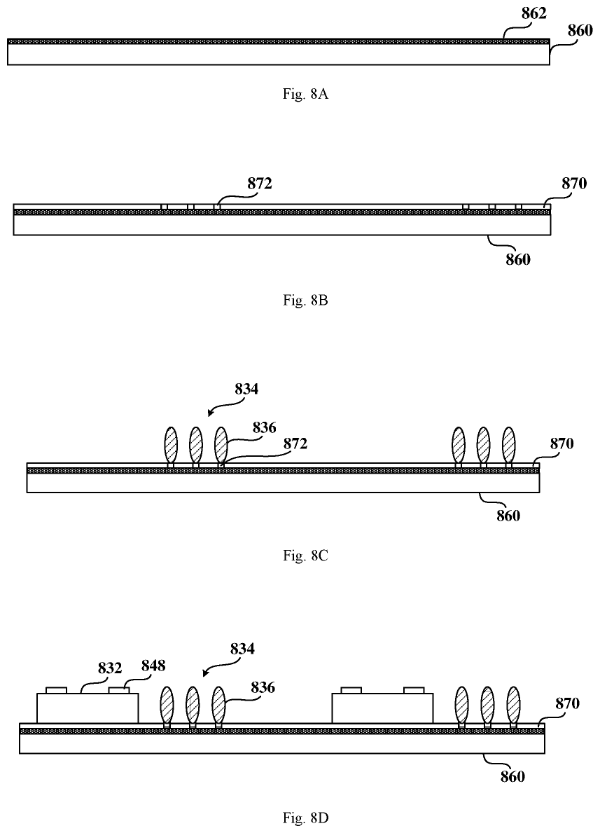

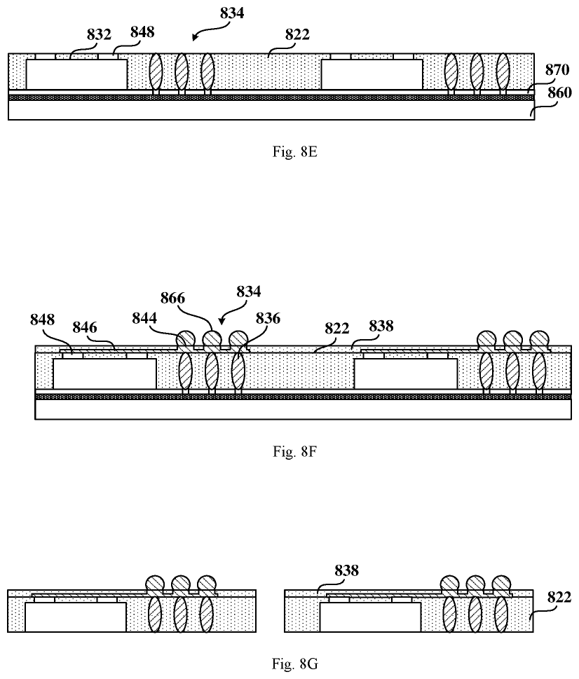

FIGS. 8A to 8G illustrate a method for making a modular semiconductor device shown in FIG. 5, according to an embodiment of the present application.

As shown in FIG. 8A, a carrier 860 such as a glass carrier or a metal carrier can be provided, with its top surface covered by a temporary bond layer 862 such as an adhesive tape. The adhesive tape can be a polyimide film, for example. The temporary bond layer 862 can protect the carrier 860 in the manufacturing process and temporarily attach the other layers and components with the carrier 860. In some embodiments, the temporary bond layer 862 can be omitted.

As shown in FIG. 8B, a temporary substrate layer 870 can be formed on the substrate 860. One or more conductive layers 872 can be formed within the temporary substrate layer 870, which function as seed patterns for one or more interlayer connection arrays to be formed thereon. In the embodiment, the conductive layers 872 extend in a vertical direction and are exposed from a top surface of the temporary substrate layer 870.

As shown in FIG. 8C, one or more interlayer connection arrays 834 are formed on the substrate 860, or particularly on the temporary substrate layer 870. In the embodiment, each interlayer connection array 834 includes a set of solder balls 836 which are attached on the conductive layers 872 within the temporary substrate layer 870.

As shown in FIG. 8D, one or more semiconductor components 832 can be placed on the temporary substrate layer 870. The semiconductor components 832 can be placed besides interlayer connection arrays 834, respectively. In particular, the semiconductor component 832 includes a component conductive pattern 848 which is oriented upward away from the carrier 860. The interlayer connection array 834 has a height equal to that of the semiconductor component 832, such that top surfaces of the solder balls 836 and the component conductive pattern 848 are generally at the same level.

Next, as shown in FIG. 8E, an encapsulant material can be deposited on the carrier 860, or particularly on the temporary substrate layer 870, to form an encapsulant layer 822. The encapsulant layer 822 can encapsulate the semiconductor component 832 and the interlayer connection array 834. The encapsulant layer 822 may be thinned, e.g., using a back-grinding process, to remove the excess encapsulant material above the semiconductor component 832 and the interlayer connection array 834.

As shown in FIG. 8F, an interposer layer 838 can be laminated on the encapsulant layer 822. The interposer layer 838 includes at least one an interposer conductive pattern 846 on an exposed surface of the interposer layer 822, and at least one interposer interconnection structure 844. The at least one interposer interconnection structure 844 is electrically coupled to the interposer conductive pattern 846, the component conductive pattern 848 and the one or more solder balls 836 of the interlayer connection array 834. Furthermore, additional solder balls 866 are bonded to the respective interposer conductive pattern 846, to facilitate the subsequent attachment process.

As shown in FIG. 8G, the encapsulant layer 822 and the interposer layer 838 which are laminated together can be singulated into individual modular semiconductor devices. Each of the modular semiconductor devices may include a semiconductor component and an interlayer connection array. Afterwards, the individual modular semiconductor devices can be removed from the carrier, and the temporary substrate layer can be removed from the singulated modular semiconductor devices as well.

It can be appreciated that the modular semiconductor devices made using the methods shown in FIGS. 7A to 7F and FIGS. 8A to 8G can be assembled with a substrate of a base semiconductor component similarly as the steps shown in FIGS. 6G to 61, which will not be elaborated herein.

The discussion herein included numerous illustrative figures that showed various steps in a method of making a modular semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A modular semiconductor device, comprising:
an encapsulant layer with an encapsulant bottom surface and an encapsulant top surface, wherein the encapsulant layer comprises a component region and an interlayer connection region;
a semiconductor component disposed within the component region, wherein the semiconductor component comprises a component conductive pattern exposed from the encapsulant bottom surface;
an interlayer connection array disposed within the interlayer connection region, wherein the interlayer connection array comprises one or more conductive vias each extending between the encapsulant bottom surface and the encapsulant top surface; and
an interposer layer laminated on the encapsulant layer and having an interposer bottom surface and an interposer top surface, wherein the interposer top surface is in contact with the encapsulant bottom surface; and wherein the interposer layer comprises an interposer conductive pattern on the interposer bottom surface, and an interposer interconnection structure which is electrically coupled to the component conductive pattern, the interposer conductive pattern and the one or more conductive vias.

2. The modular semiconductor device of claim 1, wherein the semiconductor component comprises a semiconductor die or a semiconductor package.

3. The modular semiconductor device of claim 1, wherein the conductive vias comprises conductive posts, conductive pillars or solder balls.

4. The modular semiconductor device of claim 1, wherein the encapsulant layer has a thickness equal to that of the semiconductor component.

5. The modular semiconductor device of claim 1, wherein the modular semiconductor device is formed as a single piece.

6. An electronic device, comprising:
a substrate comprising a substrate interconnection structure;
a base semiconductor component mounted on the substrate and electrically coupled to the substrate interconnection structure;
one or more base vias mounted on the substrate and electrically coupled to the substrate interconnection structure;
a first modular semiconductor device stacked over the base semiconductor component and the one or more base vias, wherein the first modular semiconductor device comprises:
an encapsulant layer with an encapsulant bottom surface and an encapsulant top surface, wherein the encapsulant layer comprises a component region and an interlayer connection region;
a semiconductor component disposed within the component region, wherein the semiconductor component comprises a component conductive pattern exposed from the encapsulant bottom surface;
an interlayer connection array disposed within the interlayer connection region, wherein the interlayer connection array comprises one or more conductive vias each extending between the encapsulant bottom surface and the encapsulant top surface; and
an interposer layer laminated on the encapsulant layer and having an interposer bottom surface and an interposer top surface, wherein the interposer top surface is in contact with the encapsulant bottom surface; and wherein the interposer layer comprises an interposer conductive pattern on the interposer bottom surface, and an interposer interconnection structure which is electrically coupled to the component conductive pattern, the interposer conductive pattern and the one or more conductive vias; and
wherein the interposer conductive pattern is electrically coupled to the one or more base vias.

7. The electronic device of claim 6, further comprising one or more additional modular semiconductor devices stacked over the first modular semiconductor device, wherein the one or more additional modular semiconductor devices have a structure substantially the same as that of the first modular semiconductor device, and wherein the first modular semiconductor device and the one or more additional modular semiconductor devices are electrically coupled together through their respective conductive vias and interposer layers.

8. The electronic device of claim 6, wherein the base semiconductor component does not fully overlap with the first modular semiconductor device.

9. The electronic device of claim 6, wherein the one or more base vias has a thickness equal to that of the base semiconductor component.

10. The electronic device of claim 6, wherein the semiconductor component of the first modular semiconductor device comprises a semiconductor die or a semiconductor package.

11. The electronic device of claim 6, wherein the conductive vias comprises conductive posts, conductive pillars or solder balls.

12. The electronic device of claim 6, wherein the encapsulant layer has a thickness equal to that of the semiconductor component.

13. The electronic device of claim 6, wherein the modular semiconductor device is formed as a single piece.

14. A method for making a modular semiconductor device, comprising:
placing on a carrier at least one semiconductor component and at least one interlayer connection array each being besides one of the at least one semiconductor component, wherein each of the at least one semiconductor component comprises a component conductive pattern which is oriented upward away from the carrier, and the interlayer connection array comprises one or more conductive vias having a height equal to that of the at least one semiconductor component;
depositing an encapsulant material on the carrier to form an encapsulant layer encapsulating the at least one semiconductor component and the at least one interlayer connection array;
thinning the encapsulant layer to expose the component conductive patterns and the at least one interlayer connection array;
laminating on the encapsulant layer an interposer layer, the interposer layer comprises at least one interposer conductive pattern on an exposed surface of the interposer layer, and at least one interposer interconnection structure which is electrically coupled to the interposer conductive pattern, the component conductive pattern of the at least one semiconductor component, and the one or more conductive vias of the interlayer connection array.

15. The method of claim 14, further comprising:
singulating the encapsulant layer and the interposer layer into individual modular semiconductor devices, wherein each of the individual modular semiconductor devices comprises a semiconductor component and an interlayer connection array.

16. The method of claim 14, wherein the at least one interlayer connection array is formed as a preformed piece.

17. The method of claim 14, the step of placing on a carrier at least one semiconductor component and at least one interlayer connection array comprising:
attaching a tape on the carrier;
attaching the at least one semiconductor component and the at least one interlayer connection array on the tape.

18. The method of claim 17, wherein the tape is an adhesive tape.

19. The method of claim 14, the step of placing on a carrier at least one semiconductor component and at least one interlayer connection array comprising:
forming a temporary substrate layer on the carrier;
forming the at least one interlayer connection array on the temporary substrate layer; and
attaching the at least one semiconductor component on the temporary substrate layer.
